(19) United States
(12) Patent Application Publication
(10) Pub. No.: US 2014/0239339 A1
(43) Pub. Date: Aug. 28, 2014

(54) A LIGHT EMITTING DEVICE COMPRISES A SAPPHIRE SUBSTRATE HAVING A PLURALITY OF OPTIMIZED CONES ON ITS SURFACE

(71) Applicant: PHECDA TECHNOLOGY CO. LTD., Taipei City (TW)

(72) Inventor: YONG-FA HUANG, Zhunan Township (TW)

(21) Appl. No.: 13/910,389

(22) Filed: Jun. 5, 2013

(30) Foreign Application Priority Data
Feb. 26, 2013 (TW) 102203623

(51) Int. Cl. H01L 33/20

(52) U.S. Cl. CPC H01L 33/20
USPC 257/99; 257/103

(57) ABSTRACT

This invention discloses a substrate for a light-emitting device and light-emitting device using the same, and the substrate comprises a sapphire substrate. The sapphire substrate comprises a surface having a plurality of cones, heights of the cones are ranged from 0.6-1.6 μm, diameters of the cones are ranged from 0.6-1.6 μm, base angles between the bottom of each of the cones and the level surface of the sapphire substrate are ranged from 40°-80°, the plurality of cones are uniformly distributed over the sapphire substrate and do not contact each other, a distance between the apexes of each two neighboring cones is ranged from 1.7-2.3 μm, a distance between the bottoms of each two neighboring cones is ranged from 0.4-1.4 μm. Further, the substrate of the light-emitting device further comprises an interlayer covering the sapphire substrate to increase the epitaxy speed and enhance the throughput subsequently.

### CROSS-REFERENCE TO RELATED APPLICATION

This application claims priority from Taiwan Patent Application No. 102203623, filed on Feb. 26, 2013 in Taiwan Intellectual Property Office, the contents of which are hereby incorporated by reference in their entirety.

### BACKGROUND OF THE INVENTION

1. Field of the Invention

This invention relates to a substrate for a light-emitting device and light-emitting device using the same, and particularly, a substrate for a light-emitting device with excellent light extraction efficiency and expedited epitaxy speed.

2. Description of the Related Art

By using the Photo-electronic Effect, modern light-emitting devices are able to convert electric energy into light forms via the recombination of stimulated electrons and holes. Semiconductor processes are already applied to mass-produce this kind of device. The modem light-emitting device with the most universal applications is the light-emitting diode (LED). Light-emitting diodes possess the advantages of long device lifetime, luminescence light-emitting, low power consumption, fast reaction speed, and zero warm-up time, etc. By adopting the semiconductor processes, light-emitting diodes further comprise the features of small size, robustness against impact, and easy to mass-produce, etc. Moreover, light-emitting diodes can be fabricated as an array or a small optical device, based on the application demands.

In recent years prices of energy sources are increasing rapidly. Therefore, pursuing energy saving and GHG mitigation have become a global tendency. To further extend the application field of the light-emitting diodes, both the academic circle and the industry focus on the research goal of how to achieve higher light-emitting efficiency with lower energy consumption. Theoretically, light emitted by the recombination of electrons and holes can radiate outside with 100% light-emitting efficiency. In reality, the internal structure and composition material of a light-emitting diode device will cause various types of light transmission losses, thus the light-emitting efficiency is reduced.

To increase the light-emitting efficiency of light-emitting diodes, pattern technology has already been applied to sapphire substrate. For example, the light-emitting diode substrate 100 shown in FIG. 1 is a sapphire substrate 110, wherein a surface 130 of the sapphire substrate 110 is allocated with a plurality of triangular pyramid structures 120 with triangle bottoms 150 to scatter the light generated within the internal of the light-emitting diode, to avoid total reflection, and to increase the probability of the light penetrating the surface of the light-emitting diode. To increase the light-emitting efficiency, the pyramid structures 104 are arranged in a densest formation.

However, pyramids have efficiency limits in scattering light and are unable to achieve optimization. Moreover, the development tendency of the pattern sapphire substrate (PSS) is toward a higher height and a smaller linewidth, the bottoms of the pyramids in the densest formation tends to interconnect with each other and increase the difficulty of the subsequent epitaxy.

### SUMMARY OF THE INVENTION

Based on the problems of the prior arts, one of the purposes of this invention is to provide a substrate for a light-emitting device to improve the problem of low light scattering efficiency of the traditional pattern sapphire substrate.

Therefore, a substrate for a light-emitting device is proposed in this invention. The substrate comprises a sapphire substrate, the sapphire substrate comprises a surface having a plurality of cones, heights of the cones are ranged from 0.6 μm to 1.6 μm, diameters of the cones are ranged from 0.6 μm to 1.6 μm, and a distance between the apexes of two neighboring cones is ranged from 1.7 μm to 2.3 μm.

Furthermore, the radius of the substrate is preferred to be 2 inches, 4 inches, 6 inches, 8 inches, or 12 inches.

Furthermore, the base angles of the cones are ranged from 40° to 80°.

Furthermore, the plurality of cones are uniformly distributed over the sapphire substrate and do not contact each other. Moreover, the distance between the bottoms of each two neighboring cones is ranged from 0.1 μm and 0.4 μm.

Furthermore, a difference between an angle formed by a tangent of any point on a line connected an apex of each cone with any point of the bottom of the cone and a horizontal line passing through the point and an angle formed by a tangent of any point of the bottom of the cone and the horizontal surface of the sapphire substrate is less than 10°.

Furthermore, the substrate of the present invention further comprises an interlayer covering the sapphire substrate and the material of the interlayer comprises aluminum nitride.

A light-emitting device is provided in this invention. The light-emitting device comprises a sapphire substrate, a first semiconductor layer, a light-emitting layer, a second semiconductor layer, a first ohmic electrode, and a second ohmic electrode. The sapphire substrate comprises a surface having a plurality of cones, heights of the cones are ranged from 06 μm to 1.6 μm, diameters of the cones are ranged from 0.6 μm to 1.6 μm, and the distance between the apexes of each two neighboring cones is ranged from 1.7 μm to 23 μm. The first semiconductor layer is allocated on the sapphire substrate. The light-emitting layer is allocated on the first semiconductor layer. The second semiconductor layer is allocated on the light-emitting layer. The first ohmic electrode contacts the first semiconductor layer. The second ohmic electrode contacts the second semiconductor layer.

Furthermore, the base angles of the cones are ranged from 40° to 80°.

Furthermore, the plurality of cones are uniformly distributed over the sapphire substrate and do not contact each other.

Furthermore, a difference between an angle formed by a tangent of any point on a line connected an apex of each cone with any point of the bottom of the cone and a horizontal line passing through the point and an angle formed by a tangent of any point of the bottom of the cone and the horizontal surface of the sapphire substrate is less than 10°.

Furthermore, a distance between the bottoms of each two neighboring cones is ranged from 0.4 μm and 1.4 μm.

Furthermore, the light-emitting device of the present invention further comprises an interlayer covering the sapphire substrate,

Furthermore, the material of the interlayer comprises aluminum nitride.

The structure of the light-emitting device of the present invention comprises a sapphire substrate to be the light-scattering surface, and the sapphire substrate has a plurality of cones. The design of the cones is able to assist the light generated within the internal of a light-emitting device, for example a light-emitting diode, to penetrate outside and adequately increase the area of the surface of the light-emitting device to reduce the difficulty of the subsequent epitaxy. Besides, the light-emitting device of the present invention further comprises an interlayer covering the sapphire substrate to expedite the epitaxy speed and increase the throughput subsequently.

As mentioned above, the substrate for the light-emitting device and the light-emitting device of the present invention may have one or more characteristics and advantages as described below:

(1) The substrate for the light-emitting device of the present invention utilizes a sapphire substrate having a plurality of cones as a light-scattering surface and is able to increase the efficiency of light penetration to outside.

(2) The substrate for the light-emitting device of the present invention further comprises an interlayer covering the sapphire substrate to expedite the epitaxy speed and increase the throughput subsequently.

In order to provide farther understanding of the technical characteristics and the efficiency of the present invention, the same components in the following embodiments are labeled as the same numeral.

### BRIEF DESCRIPTION OF THE DRAWINGS

FIG. 1 is a three dimensional diagram showing a substrate for a light-emitting device according to a prior art.

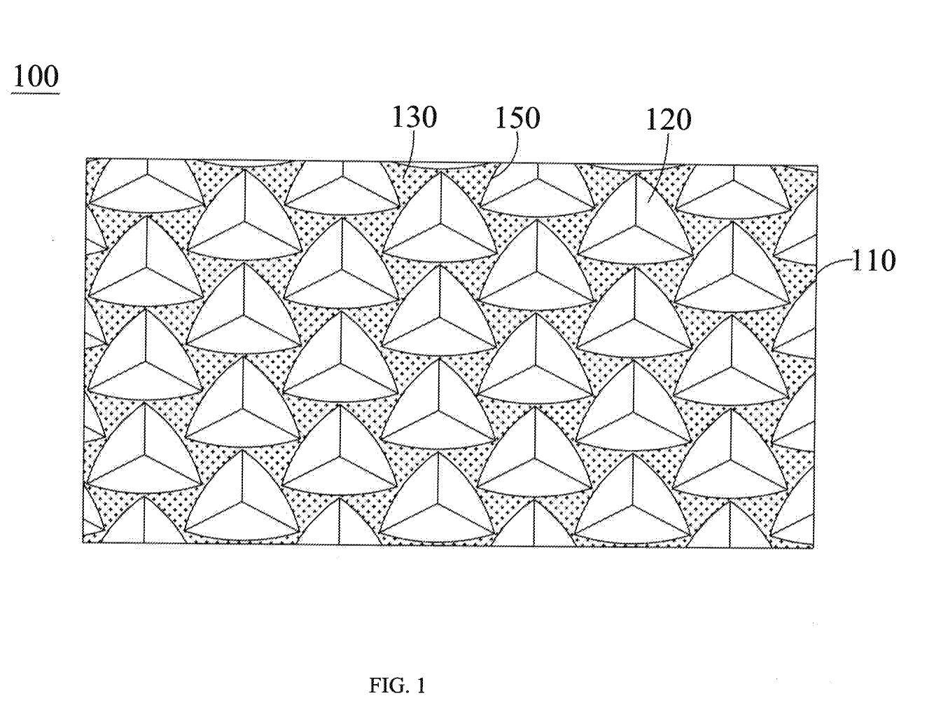

FIG. 2 is a top view diagram showing a substrate for a light-emitting device according to the preferred embodiment of the present invention.

FIG. 3 is a side view diagram showing a substrate for a light-emitting device according to the preferred embodiment of the present invention.

FIG. 4 is an inclined angle diagram of a cone's slant plane showing a substrate for a light-emitting device according to the preferred embodiment of the present invention.

FIG. 5 is a diagram of an interlayer covering a sapphire substrate showing a substrate for a light-emitting device according to the preferred embodiment of the present invention.

FIG. 6 is a sectional view diagram showing a light-emitting device according to the preferred embodiment of the present invention.

### DETAILED DESCRIPTION OF THE PREFERRED EMBODIMENTS

With reference to the drawings, thereafter, the preferred embodiment of a substrate for a light-emitting device in accordance with the present invention is illustrated. In order to be understood easily, the same components in the preferred embodiment are labeled as the same numeral.

The present invention discloses a substrate for a light-emitting device, and the substrate is suitable for improving the efficiency of using pyramids installed on the pattern sapphire substrate to scatter light and solving the interconnection problem of the bottoms of dense disposition. The substrate of the present invention comprises a sapphire substrate, and the sapphire substrate comprises a surface having a plurality of cones. The design of the cones is able to assist the light generated within the internal of a light-emitting device, for example a light-emitting diode, to penetrate outside and adequately increases the area of the surface of the light-emitting device to reduce the difficulty of the subsequent epitaxy. Moreover, the substrate of the present invention further comprises an interlayer covering the sapphire substrate to expedite the epitaxy speed and increase the throughput subsequently. The substrate of the present invention is designed to be suitable for various kinds of light-emitting devices, for example a light-emitting diode.

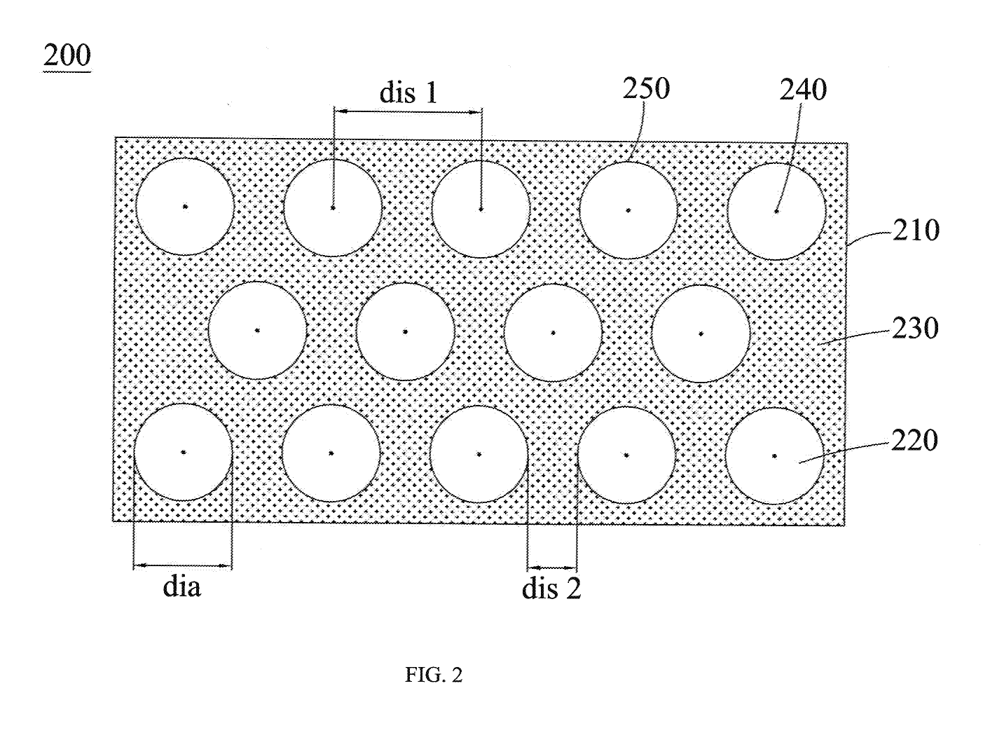

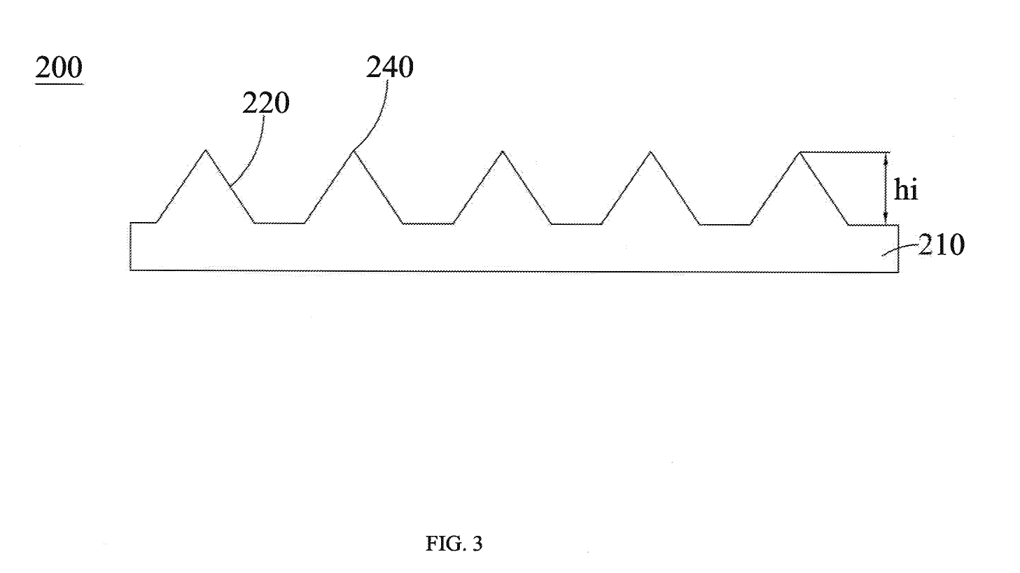

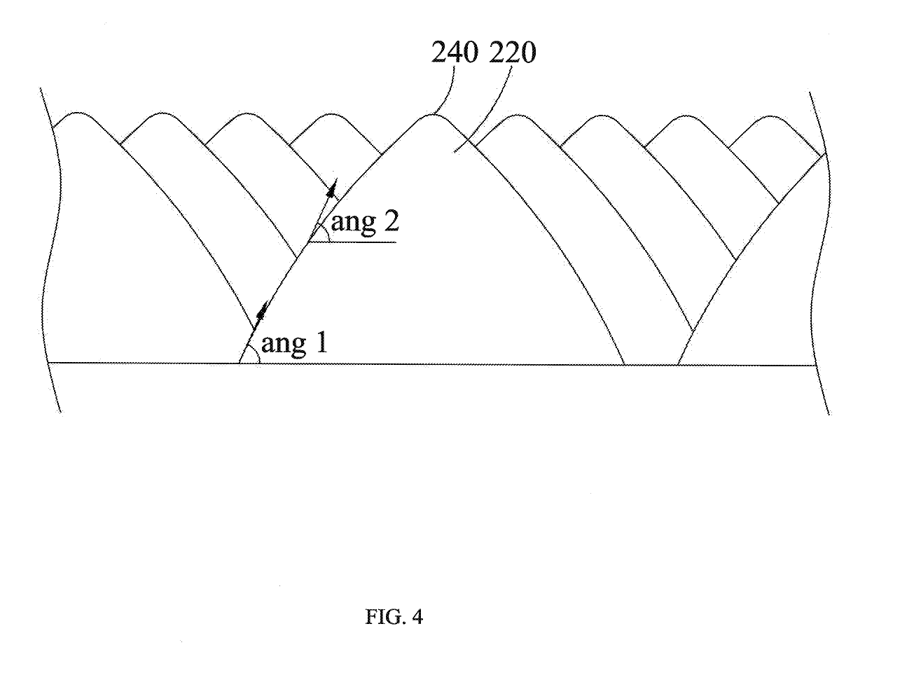

Refer to FIG. 2, FIG. 3, and FIG. 4, FIG. 2 is a top view diagram showing a substrate for a light-emitting device according to the preferred embodiment of the present invention, FIG. 3 is a side view diagram showing a substrate for a light-emitting device according to the preferred embodiment of the present invention, and FIG. 4 is an inclined angle diagram of a cone's slant plane showing a substrate for a light-emitting device according to the preferred embodiment of the present invention, In FIG. 2 the substrate 200 comprises the sapphire substrate 210, wherein the sapphire substrate 210 comprising a surface 230 having a plurality of cones 220. The radius of the substrate of the present invention is preferred to be 2 inches, 4 inches, 6 inches, 8 inches, or 12 inches.

Furthermore, for the substrate 200 of the present invention the diameters of the cones are ranged from 0.6 μm to 1.6 μm.

Furthermore, for the substrate 200 of the present invention the plurality of cones 220 are uniformly distributed over the sapphire substrate 210 and do not contact each other. Moreover, the distance dis 1 between the apexes 240 of each two neighboring cones 220 is ranged from 1.7 μm to 2.3 μm, and the distance dis 2 between the bottoms 250 of each two neighboring cones 220 is ranged from 0.4 μm and 1.4 μm.

Furthermore, as shown in FIG. 4, for the substrate 200 of the present invention the base angles of the cones 220 are ranged from 40° to 80°. Moreover, for the substrate 200 of the present invention a difference between an angle (the inclined angle ang 2 of the cone slant) formed by a tangent of any point on a line connected an apex 240 of each cone 220 and any point of the bottom 250 of the cone and a horizontal line passing through the point and an angle (the base angle ang 1 of the cone bottom) formed by a tangent of any point of the bottom 250 of the cone 220 and the horizontal surface of the sapphire substrate is less than 10°. Preferably, the first tangent and the second tangent are located on a surface vertical to the horizontal surface of the sapphire substrate 210.

Furthermore, for the substrate 200 of the present invention eights hi of the cones 220 are ranged from 1.4 μm to 1.9 μm.

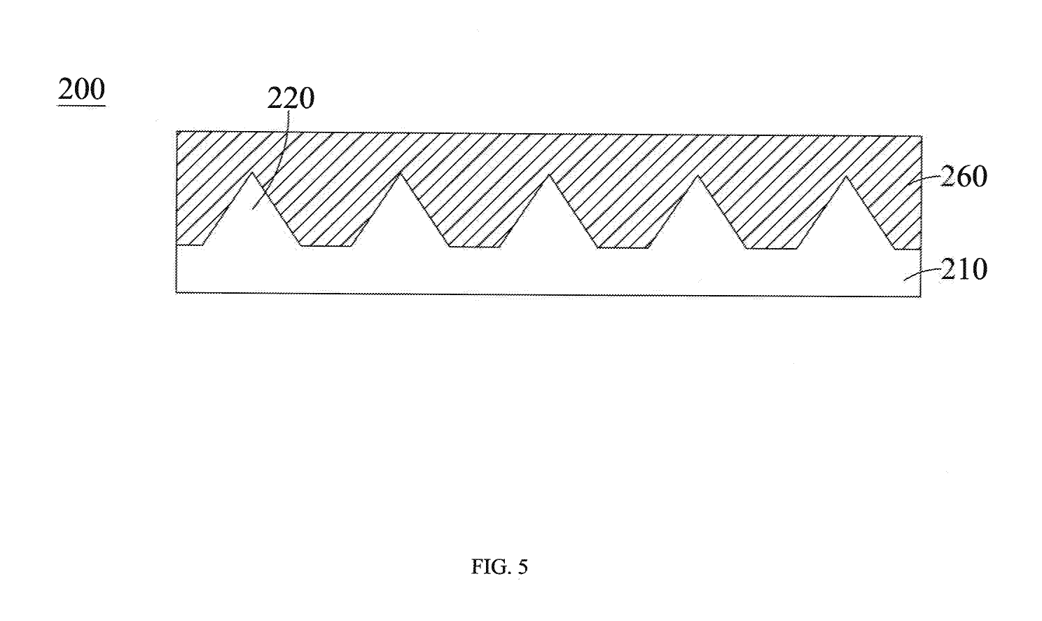

Refer to FIG. 5, FIG. 5 is a diagram of an interlayer covering a sapphire substrate showing a substrate for a light-emitting device according to the preferred embodiment of the present invention. The substrate 200 of the present invention further comprises an interlayer 60 covering the sapphire substrate 210, and the material of the interlayer 260 comprises aluminum nitride.

In summation, the structure of the substrate for a light-emitting device of the present invention comprises a sapphire substrate having a plurality of cones to be the light-scattering surface. The design of the cones is able to assist the light generated within the internal of a light-emitting device to penetrate outside and adequately increase the area of the surface of the light-emitting device to reduce the difficulty of the subsequent epitaxy. Moreover, the light-emitting device of the present invention further comprises an interlayer covering the sapphire substrate to expedite the epitaxy speed and increase the throughput subsequently.

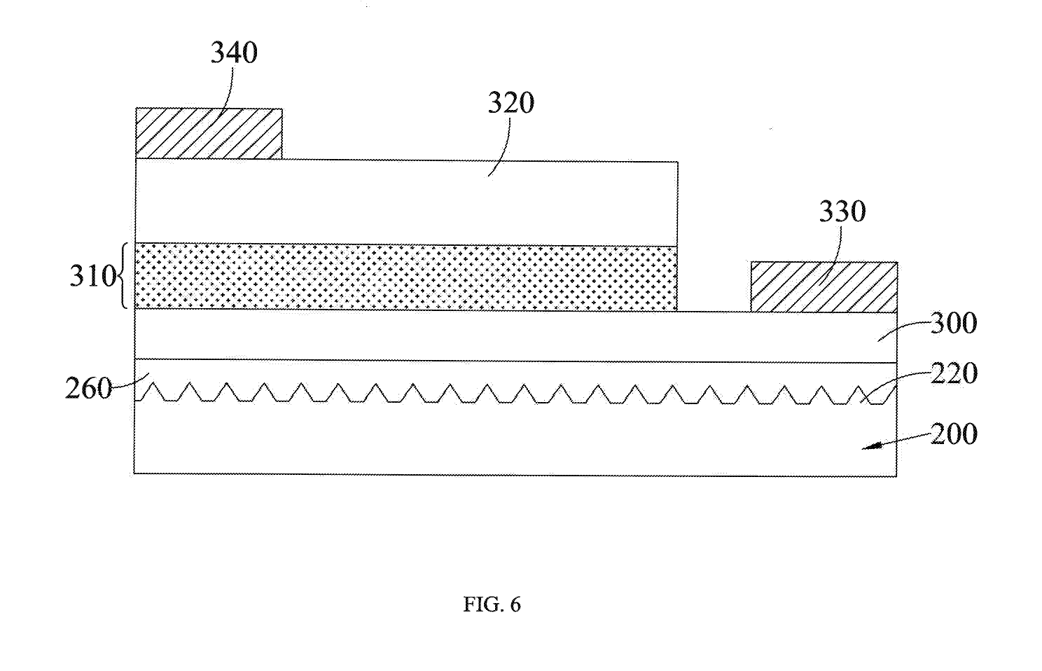

FIG. 6 is a sectional view diagram showing a light-emitting device according to the preferred embodiment of the present invention.

Refer to FIG. 6, FIG. 6 is an embodiment of a light-emitting diode using the substrate 200 of the present invention as the light-emitting device. The light-emitting diode comprises a sapphire substrate 200, an interlayer 260 on the sapphire substrate 200, a first semiconductor layer 300 on the interlayer 260, a light-emitting layer 310 on the first semiconductor layer 300, a second semiconductor layer 320 on the light-emitting layer 310, a first ohmic electrode 330 connected to the first semiconductor layer 300, and a second ohmic electrode 340 connected to second semiconductor layer 320. The interlayer 260 is allocated on the sapphire substrate 200 to expedite the epitaxy speed and increase the throughput subsequently. Besides, the interlayer may be eliminated from the light-emitting diode, based on practical needs, and the first semiconductor 300 is directly covered the sapphire substrate 200. However, this embodiment does not depart from the teachings of the present invention.

Furthermore, the first semiconductor 300, the light-emitting layer 310, and the second semiconductor 320 may belong to the III-V group, for example the gallium nitride family semiconductor. The first and the second ohmic electrodes may be selected from a single alloy or a multilayer film from the family comprising oxides and nitrides of nickel, lead, cobalt, iron, titanium, copper, rhodium, gold, ruthenium, tungsten, zirconium, molybdenum, silver, or similar elements, respectively. Besides, the first and the second ohmic electrodes may be selected from a single alloy or a multilayer film from the family comprising rhodium, iridium, silver, alumimum, respectively.

The present invention has been described with reference to the foregoing preferred embodiments, it will be understood that the invention is not limited to the details thereof. Various equivalent variations and modifications may still occur to those skilled in this art in view of the teachings of the present invention. Thus, all such variations and equivalent modifications are also embraced within the scope of the invention as defined in the appended claims.

1. A substrate for a light-emitting device comprising a sapphire substrate, wherein the sapphire substrate comprises a surface having a plurality of cones, heights of the cones are ranged from 0.6 μm to 1.6 μm, diameters of the cones are ranged from 0.6 μm to 1.6 μm, and a distance between the apexes of each two neighboring cones is ranged from 1.7 μm to 2.3 μm; wherein the base angles of the cones are ranged from 40° to 80° and the plurality of cones do not include cylinders.

2. The substrate of claim 1, wherein the radius of the substrate is 2 inches, 4 inches, 6 inches, 8 inches, or 12 inches.

3. (canceled)

4. The substrate of claim 1, wherein the plurality of cones are uniformly distributed on the sapphire substrate.

5. The substrate of claim 4, wherein the plurality of cones do not contact each other.

6. The substrate of claim 1, wherein a difference between an angle formed by a tangent of any point on a line connected an apex of each cone with any point of the bottom of the cone and a horizontal line passing through the point and an angle formed by a tangent of any point of the bottom of the cone and the horizontal surface of the sapphire substrate is less than 10°.

7. The substrate of claim 1, wherein the distance between the bottoms of each two neighboring cones is ranged from 0.4 μm and 1.4 μm.

8. The substrate of claim 1, further comprising an interlayer covering the sapphire substrate.

9. The substrate of claim 8, wherein the material of the interlayer comprises aluminum nitride.

10. A light-emitting device, comprising:
a sapphire substrate, comprising a surface having a plurality of cones, wherein heights of the cones are ranged from 0.6 μm to 1.6 μm, diameters of the cones are ranged from 0.6 μm to 1.6 μm, and a distance between apexes of each two neighboring cones is ranged from 1.7 μm to 2.3 μm;
a first semiconductor layer, being allocated on the sapphire substrate;
a light-emitting layer, being allocated on the first semiconductor layer;
a second semiconductor layer, being allocated over the light-emitting layer;
a first ohmic electrode, contacting the first semiconductor layer; and
a second ohmic electrode, contacting the second semiconductor layer;
wherein the base angles of the cones are ranged from 40° to 80° and the plurality of cones do not include cylinders.

11. (canceled)

12. The light-emitting device of claim 10, wherein the plurality of cones are uniformly distributed over the sapphire substrate.

13. The light-emitting device of claim 12, wherein the plurality of cones do not contact each other.

14. The light-emitting device of claim 10, wherein a difference between an angle formed by a tangent of any point on a line connected an apex of each cone with any point of the bottom of the cone and a horizontal line passing through the point and an angle formed by a tangent of any point of the bottom of the cone and the horizontal surface of the sapphire substrate is less than 10°.

15. The light-emitting device of claim 10, wherein the distance between the bottoms of each two neighboring cones is ranged from 0.4 μm and 1.4 μm.

16. The light-emitting device of claim 10, wherein the substrate further comprises an interlayer covering the sapphire substrate.

17. The light-emitting device of claim 16, wherein the material of the interlayer comprises aluminum nitride.
